(19) United States
(12) Patent Application Publication
(10) Pub. No.: US 2026/0006713 A1
(43) Pub. Date: Jan. 1, 2026

(54) HYBRID COOLING SYSTEM AND ELECTROMAGNETIC INTERFERENCE SHIELD

(71) Applicant: Intel Corporation, Santa Clara, CA (US)

(72) Inventors: Kari Pekka Johannes Mansukoski, Hillsboro, OR (US); Sami M. Heinisuo, Dallas, OR (US); Jeff Ku, Taipei City (TW); Luis Carlos Paniagua Acuña, Santa Ana (CR); Shawn S. McEuen, Portland, OR (US)

(73) Assignee: Intel Corporation, Santa Clara, CA (US)

(21) Appl. No.: 18/758,041

(22) Filed: Jun. 28, 2024

(51) Int. Cl. H05K 1/02; H05K 7/20; H05K 9/00

(52) U.S. Cl. CPC H05K 1/0203; H05K 7/20136; H05K 7/20336; H05K 7/20409; H05K 9/0024; H05K 9/0039; H05K 2201/066; H05K 2201/10734

(57) ABSTRACT

Devices and systems for cooling and shielding electromagnetic interference (EMI) are disclosed herein. In one example, a device includes a vapor chamber and one or more heat pipes coupled to the vapor chamber, where the heat pipes are at least partially below the vapor chamber. The heat pipes are to be coupled to a circuit board such that the heat pipes and the vapor chamber form at least a portion of an EMI shield around at least a portion of integrated circuitry on the circuit board.

### BACKGROUND

Many electronic devices use electromagnetic interference (EMI) shields to block or reduce EMI. Many electronic devices also use active cooling systems to prevent electronic components from overheating. For example, an electronic device may include an EMI shield around certain electronic components to reduce EMI, and the electronic device may include a cooling system to actively cool those same components and prevent them from overheating. The EMI shield and the cooling system both take up space in the device, which increases the overall device size.

### BRIEF DESCRIPTION OF THE DRAWINGS

FIG. 1 illustrates a cross-section view of a system that includes a hybrid cooler and electromagnetic interference (EMI) shield with one or more heat pipes routed below a vapor chamber and along the surface of a printed circuit board (PCB).

FIG. 2 illustrates a cross-section view of a system that includes a hybrid cooler and EMI shield with one or more heat pipes routed below a vapor chamber and along the sides of a PCB.

FIG. 3 illustrates a perspective view of a system that includes a hybrid cooler and EMI shield with a heat pipe and vapor chamber as the sidewalls and lid of the EMI shield.

FIGS. 4A-C illustrate perspective views of a system that includes a hybrid cooler and EMI shield with a heat pipe grounding guide.

FIGS. 5A-C illustrate perspective views of a system that includes a hybrid EMI shield cooler with an EMI gasket to ground the heat pipes.

FIGS. 6A-C illustrate various grounding mechanisms for a hybrid cooler and EMI shield with heat pipes routed along the sides of a PCB.

FIGS. 7A-B illustrate graphs of the performance of a hybrid EMI shield cooling system with respect to shielding EMI from nearby Wi-Fi antennas.

FIG. 8 illustrates a cross-section side view of an integrated circuit device assembly in accordance with certain embodiments.

FIG. 9 illustrates a block diagram of an example electrical device in accordance with certain embodiments.

### DETAILED DESCRIPTION

Electronic devices may use electromagnetic interference (EMI) shields to block or reduce electromagnetic interference. As an example, an electronic device may use an EMI shield to limit radio frequency (RF) interference and other forms of EMI within the device and between the device and the external world. EMI refers to a disturbance caused by an electromagnetic field that can potentially disrupt the operation of an electronic device, which may lead to reduced performance, reliability, and/or safety. Effective EMI mitigation techniques, such as EMI shielding and grounding, are crucial to prevent or minimize negative effects from EMI and ensure proper functioning of an electronic device. EMI shields (which may also be referred to as EMI fences, cans, cages, etc.) are devices designed to block or reduce EMI between electronic components. EMI shields come in a variety of forms—including enclosures, cans, cages, covers, barriers, and sheets—and may be designed to fully or partially enclose electronic components. Moreover, EMI shields are typically made of conductive materials that absorb or reflect electromagnetic waves (e.g., metals such as aluminum, copper), which prevents them from penetrating or escaping the shielded area. Accordingly, EMI shields play an important role in minimizing EMI and ensuring the reliable operation of electronic devices and systems.

Electronic devices may also use active cooling systems to prevent electronic components from overheating. Cooling systems come in a variety of forms and may include components such as heat pipes, vapor chambers, heat exchangers, fans, water blocks, and so forth.

In some cases, an electronic device may include both an EMI shield and a cooling system. For example, an EMI shield may be used to enclose certain components on a printed circuit board (PCB) to reduce EMI, such as a system-on-a-chip (SoC), processors, memory, voltage regulators, and so forth. Moreover, a cooling system may be used to actively cool those components and prevent them from overheating. The EMI shield and the cooling system are typically implemented as separate devices that each take up space and contribute to the overall size of a system. For example, the EMI shield may be a standalone enclosure soldered to ground connections on the PCB, which takes up space on the surface of the PCB and increases the PCB size. Similarly, the cooling system may include various components mounted on or over the PCB, such as a heat pipe and vapor chamber. In a cooling system where a heat pipe is used with a vapor chamber, the heat pipe is typically mounted on top of the vapor chamber, which may increase the system thickness by approximately 1-1.2 millimeters (mm) or more.

Accordingly, this disclosure presents embodiments of a hybrid cooling system and EMI shield where certain components in the cooling system also serve as the EMI shield. In some embodiments, for example, the cooling system may include a vapor chamber and one or more heat pipes. The heat pipes may be connected under the vapor chamber and may be routed along the surface of the PCB (e.g., along the PCB edges) or along the sides of the PCB (e.g., outside the PCB perimeter). The heat pipes may also be connected to the main ground (GND) of the PCB via low-impedance electrical connections. In this manner, the vapor chamber functions as the lid of the EMI shield, and the heat pipes function as the sidewalls or fence of the EMI shield while also grounding the EMI shield (e.g., via the connections from the heat pipes to the main ground of the PCB).

The described embodiments may provide various advantages. For example, since the heat pipes may be routed below the vapor chamber (e.g., along the surface or sides of the PCB instead of above the vapor chamber), the system thickness can be reduced significantly, and/or the heat pipe thickness can be increased to maximize thermal cooling capacity without increasing the overall system thickness. Moreover, when the heat pipes are routed alongside the PCB (e.g., outside the PCB perimeter), the heat pipes do not consume any space on the surface of the PCB, which enables the size of the PCB to be reduced (e.g., by reducing the X/Y dimensions or length/width). The described embodiments are also capable of providing very good EMI shielding performance with a full EMI enclosure. Further, since the cooling system and the EMI shield share certain components, the total number of components/parts is reduced, which may decrease costs and improve sustainability, while also providing easier repairability (e.g., since a separate EMI shield lid is not needed).

FIG. 1 illustrates a cross-section view of a system 100 that includes a hybrid cooler and electromagnetic interference (EMI) shield with one or more heat pipes 106 routed below a vapor chamber 108 and along the surface of a printed circuit board (PCB) 102. In particular, system 100 includes an integrated circuit (IC) package 104 (e.g., a system-on-a-chip (SoC), microprocessors, memory, voltage regulators) on the top surface of the PCB 102, which is attached and electrically coupled to the PCB 102 via a ball grid array (BGA) interconnect 103. The heat pipes 106 are attached to the top surface of the PCB 102 and are routed around the IC package 104, such that the heat pipes 106 at least partially surround the IC package 104. The heat pipes 106 are also electrically coupled to the main ground (GND) plane of the PCB 102 via conductive ground contacts (not shown) (e.g., ground pads or strips) on the top surface of the PCB 102. The heat pipes 106 are further attached and thermally coupled to the bottom surface of the vapor chamber 108, such that the heat pipes 106 are routed under or below the vapor chamber 108. Moreover, the vapor chamber 108 extends over, and is thermally coupled to, the top surface of the IC package 104. In this manner, the heat pipes 106 and the vapor chamber 108 function as both a cooling system and an EMI shield for the IC package 104.

For example, when the IC package 104 generates heat, the heat may be transferred from the IC package 104 to the vapor chamber 108, spread through the vapor chamber 108 to the heat pipes 106, and then routed through the heat pipes 106 to other thermal management components (e.g., heat exchangers, fans, water blocks, etc.), where the heat is eventually dissipated, thus cooling the IC package 104.

The heat pipes 106 and the vapor chamber 108 also form an enclosure around the IC package 104 that functions as an EMI shield (e.g., by substantially enclosing the IC package 104 on the PCB 102). For example, the heat pipes 106 are below or under the vapor chamber 108 and extend around the sides of the IC package 104, and the vapor chamber 108 is above or over the heat pipes 106 and covers the top of the IC package 104. In this manner, the heat pipes 106 function as the sidewalls of the EMI shield, and the vapor chamber 108 functions as the lid of the EMI shield. Moreover, the EMI shield is grounded via the electrical connections between the heat pipes 106 and the main ground (GND) plane of the PCB 102.

In this manner, since the heat pipes 106 and vapor chamber 108 function as both a cooling system and an EMI shield, separate cooling system and EMI shield components are no longer necessary, which may reduce the part count, decrease costs, improve sustainability, and facilitate easier repairability. Moreover, since the heat pipes 106 are routed below the vapor chamber 108 (e.g., instead of above the vapor chamber 108), the thickness of the system 100 may be significantly reduced.

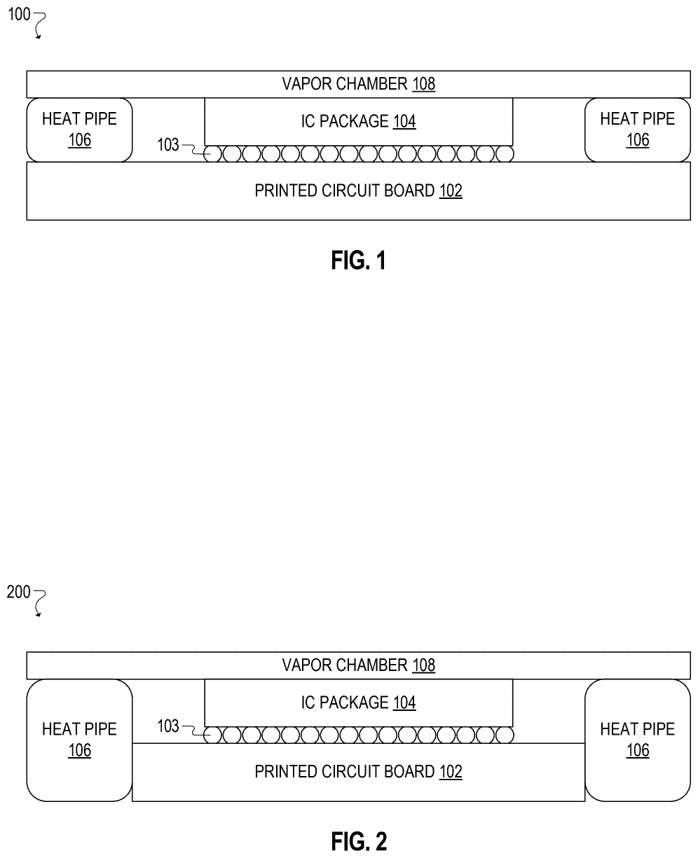

FIG. 2 illustrates a cross-section view of a system 200 that includes a hybrid cooler and EMI shield with one or more heat pipes 106 routed below a vapor chamber 108 and along the sides of a PCB 102. In the illustrated embodiment, system 200 is similar to system 100 of FIG. 1, except the heat pipes 106 are routed along the sides of the PCB 102 (e.g., outside the edges/perimeter of the PCB 102 instead of along the surface of the PCB 102), the PCB 102 is smaller, and the heat pipes 106 are thicker. In particular, by routing the heat pipes 106 along the sides of the PCB 102 instead of along the surface, the size of the PCB 102 can be reduced since the heat pipes 106 do not consume any space on the surface of the PCB 102, and the thickness of the heat pipes 106 can be increased (e.g., to maximize thermal cooling capacity for high-power systems) without increasing the overall thickness of the system 200 since the heat pipes 106 are next to the PCB 102 instead of on top of it.

In systems 100 and 200 of FIGS. 1 and 2, the heat pipes 106 and vapor chamber 108 should be properly grounded to function as an effective EMI shield. For example, as explained above, the heat pipes 106 may be electrically coupled to the main ground (GND) plane of the PCB 102 via conductive ground contacts (not shown) on the top surface of the PCB 102. These ground connections may be implemented using various approaches depending on the embodiment.

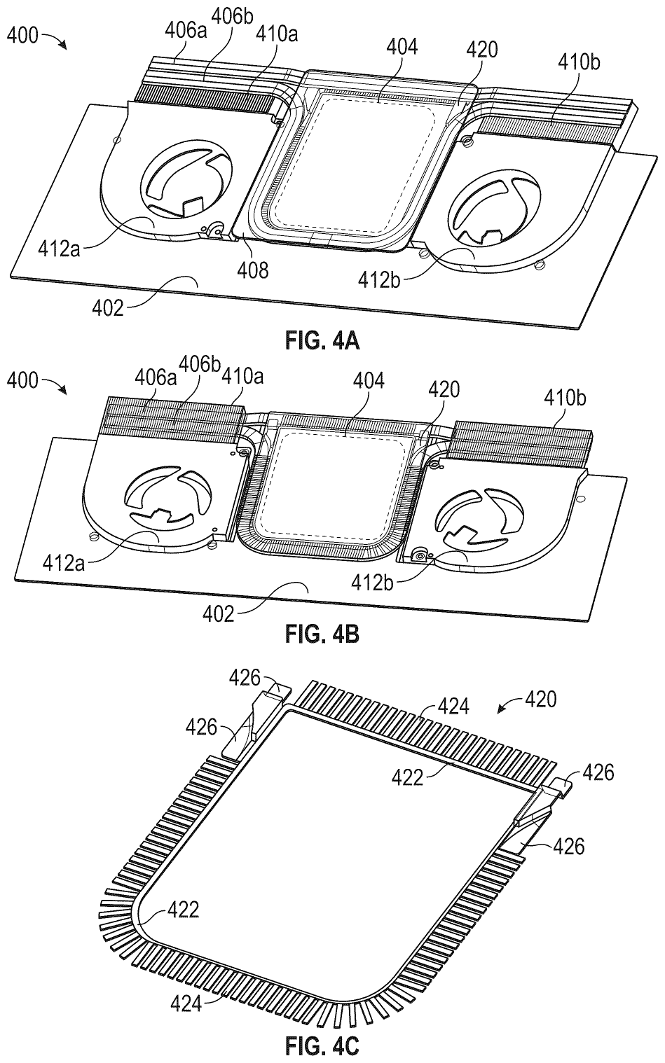

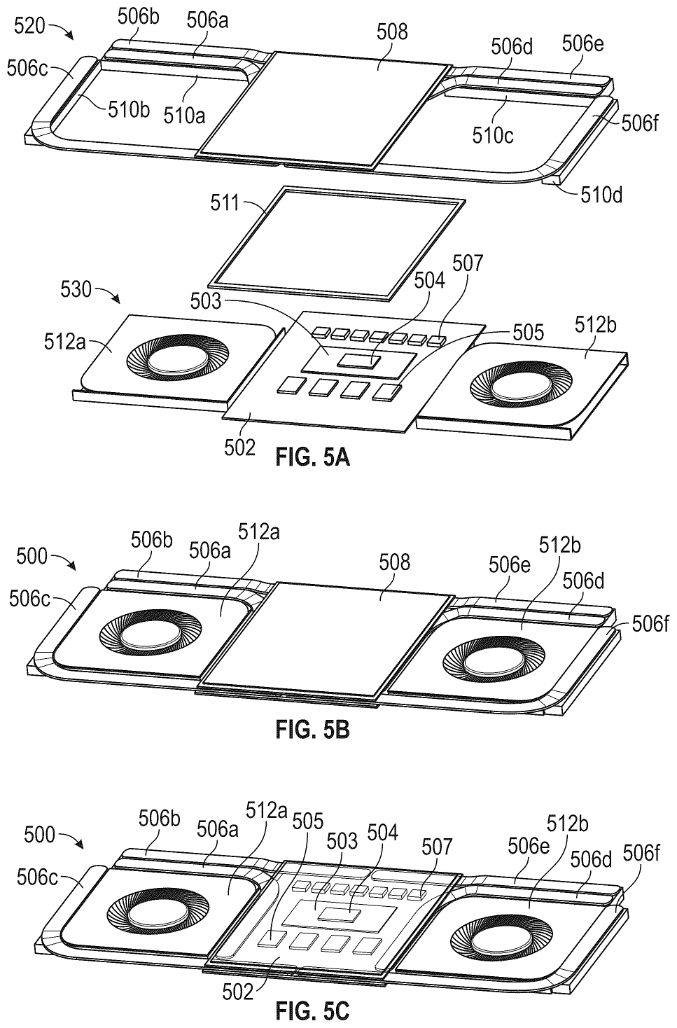

In system 100, for example, where the heat pipes 106 are routed on the surface of the PCB 102, the ground connections may be implemented using common grounding approaches, such as a conductive gasket or foam inserted between the heat pipes 106 and the ground contacts on the PCB 102 (as shown in FIGS. 5A-C), or conductive clips soldered to the ground contacts on the PCB 102 and clipped onto the heat pipes 106. Alternatively, the ground connections may be implemented using a conductive heat pipe grounding guide 420 soldered to the ground contacts on the PCB 102 (as shown in FIGS. 4A-C).

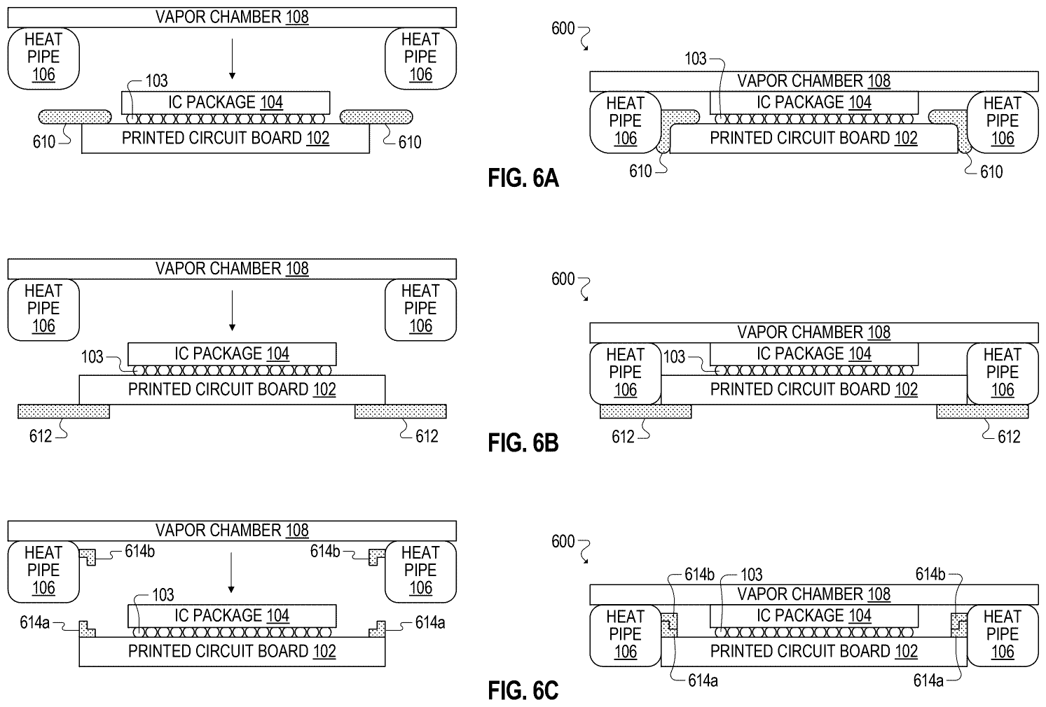

In system 200, where the heat pipes 106 are routed on the sides of the PCB 102, the ground connections may be implemented using any of the grounding approaches shown in FIGS. 6A-C, or by modifying the heat pipe grounding guide 420 of FIGS. 4A-C to enable attachment to the sides/edges of the PCB 102 instead of the surface of the PCB 102.

It should be appreciated that systems 100 and 200 are merely shown as examples and numerous variations and alternative embodiments are also within the scope of this disclosure. In various embodiments, for example, certain components of systems 100, 200 may be modified, replaced, rearranged, omitted, and/or added.

In particular, systems 100, 200 may include any number of heat pipes 106 or vapor chambers 108. In FIGS. 1 and 2, for example, the cross-section views of system 100, 200 may be depicting two sections of the same heat pipe 106 or sections of two different heat pipes 106. Moreover, the heat pipes 106 may be routed or may extend around all or only some sides of the IC package 104, while other components (e.g., planar sidewalls) may extend around any remaining sides of the IC package 104 where the heat pipes 106 are not present.

In some embodiments, the vapor chamber 108 may be omitted and/or replaced with one or more other components, such as a cold plate or another cooling component, or a standard EMI shield lid.

A heat pipe 106 may refer to a tubular enclosure that uses principles of evaporation and condensation to efficiently transfer and dissipate heat from one point to another. For example, a heat pipe 106 may include a hollow tubular enclosure made of conductive materials (e.g., copper or aluminum) that contains a wick lining on its inner walls and a working fluid (e.g., water, ammonia, acetone, methanol). When the hot end of the heat pipe 106 is exposed to heat, the working fluid inside the heat pipe 106 absorbs the heat and evaporates into vapor. The vapor then flows through the hollow cavity to the cool end of the heat pipe 106. At the cool end, the vapor cools and condenses back into liquid, thus releasing the heat (e.g., into the surrounding environment and/or a cooling medium). The condensed liquid is then drawn back to the hot end (e.g., through the capillary action of the wick) and the cycle continues.

A vapor chamber 108 may refer to a relatively flat enclosure that uses principles of evaporation and condensation to spread heat uniformly over its surface area and efficiently transfer and dissipate the heat. In some cases, a vapor chamber 108 may include similar components as a heat pipe 106 and may spread and dissipate heat using similar principles, except a vapor chamber 108 is typically flat while a heat pipe 106 is typically tubular. For example, a vapor chamber 108 may include a relatively flat enclosure made of conductive materials (e.g., copper or aluminum) with a wick lining its inner walls and a working fluid inside the enclosure.

The IC package 104 may include one or more IC dies (e.g., on a package substrate) containing any type or combination of integrated circuitry, including, without limitation, one or more systems-on-a-chip (SoCs), microprocessors (e.g., central processing units (CPUs), graphics processing units (GPUs), vision processing units (VPUs), neural processing units (NPUs), other XPUs), field-programmable gate arrays (FPGAs), application-specific integrated circuits (ASICs), network interface controllers (NICs), persistent storage devices, input/output (I/O) devices and controllers, memory devices and controllers, and/or voltage regulators, among other components.

An SoC may include a variety of components integrated on the same die, chip, or package, including, without limitation, any of the components referenced above with respect to IC package 104. In various embodiments, some or all components of an SoC may be implemented as standalone components (e.g., disintegrated from the SoC), which may be individually or separately coupled to the PCB 102.

In various embodiments, systems 100, 200 may include any number of IC packages 104 and/or other electronic components (e.g., SoCs, XPUs, FPGAs, ASICs, memory chips, voltage regulators) under the same or different hybrid cooler and EMI shields.

Systems 100, 200 may include a variety of other components (not shown), such as other thermal management components (e.g., heat sinks, heat spreaders, heat exchangers, fans, water blocks), input/output (I/O) devices (e.g., display, keyboard, mouse, sensors), communication interfaces, antennas, etc.

In this disclosure, “hybrid cooler and EMI shield” and “hybrid EMI shield cooler,” and variations thereof, may refer to one or more components that collectively function as both a cooling system and an EMI shield (e.g., a vapor chamber 108 and one or more heat pipes 106 routed below the vapor chamber 108). A hybrid cooler and EMI shield may be used with any electronic components (e.g., IC package 104) that may benefit from cooling and EMI shielding.

In this disclosure, components that are “thermally coupled” may be directly or indirectly coupled in a manner that facilitates the transfer of thermal energy (e.g., heat).

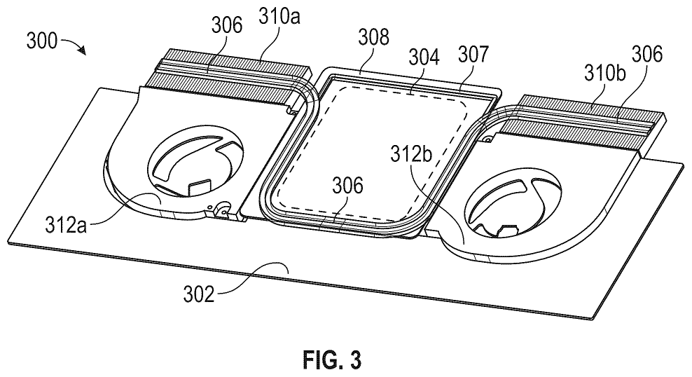

Embodiments of hybrid coolers and EMI shields are described in further detail in connection with FIGS. 3-7. The concepts described above with respect to systems 100, 200, including the modifications and variations thereof, also apply to the other embodiments of hybrid coolers and EMI shields described throughout this disclosure (and vice versa).

FIG. 3 illustrates a perspective view of a system 300 that includes a hybrid cooler and EMI shield with a heat pipe 306 and vapor chamber 308 as the sidewalls and lid of the EMI shield. In particular, the heat pipe 306 and vapor chamber 308 are used as a cooling system and EMI shield for a system-on-a-chip (SoC) core 304, which may refer to an area of a printed circuit board (PCB) 302 that contains an SoC and other core components associated with, but separate from, the SoC (e.g., memory, voltage regulators).

In the illustrated embodiment, system 300 includes multiple fans 312a-b on the PCB 302 (e.g., adjacent to the SoC core 302), along with multiple heat exchangers 310a-b adjacent to the respective fans 312a-b, which are thermally coupled to the ends of the heat pipe 306.

The heat pipe 306 is routed across the system 300, starting at one of the heat exchangers 310a, then under the vapor chamber 308 and on the surface of the PCB 302 along the west, south, and cast sides of the SoC core 304, and then to the other heat exchanger 310b. A partial EMI sidewall 307 extends around the remaining sides of the SoC core 304, including the north side and portions of the east and west sides. The partial EMI sidewall 307 may be any sidewall structure that shields EMI, such as a conductive planar (e.g., flat) sidewall, a conductive gasket/foam, etc. The heat pipe 306 and the partial EMI sidewall 307 are coupled to the bottom surface of the vapor chamber 308, which extends over the SoC core 304. In this manner, the heat pipe 306 and the partial EMI sidewall 307 collectively surround the SoC core 304 on all sides, and the vapor chamber 308 covers the top of the SoC core 304, thus forming an enclosure around the SoC core 304. The heat pipe 306 and the partial EMI sidewall 307 are also electrically coupled to ground contacts (not shown) on the top surface of the PCB 302 (e.g., using a conductive gasket/foam, solder-down clips, heat pipe grounding guide 420, etc.), which in turn are connected to the main ground (GND) plane of the PCB 302. In this manner, the heat pipe 306, the partial EMI sidewall 307, and the vapor chamber 308 collectively function as both a cooling system and an EMI shield for the SoC core 304.

For example, when components in the SoC core 304 generate heat, the heat may be transferred from the SoC core 304 to the vapor chamber 308, spread through the vapor chamber 308 to the heat pipe 306, and then routed through the heat pipe 306 to the heat exchangers 310a-b, which are cooled by the fans 312a-b to dissipate the heat.

Moreover, the heat pipe 306, the partial EMI sidewall 307, and the vapor chamber 308 also form an EMI shield around the components in the SoC core 304. In particular, the heat pipe 306 and the partial EMI sidewall 307 form the sidewalls of the EMI shield, and the vapor chamber 308 forms the lid of the EMI shield. Moreover, the EMI shield is grounded via the electrical connections from the heat pipe 306 and the partial EMI sidewall 307 to the main ground (GND) plane of the PCB 302.

In other embodiments, any arrangement of heat pipes 306 and partial EMI sidewalls 307 may be used to form the EMI shield sidewalls around the SoC core 304. For example, heat pipes 306 may be used as the EMI sidewalls on the east and west sides of the SoC core 304 (e.g., adjacent to the fans 312a-b), while partial EMI sidewalls 307 may be used on the north and south sides of the SoC core 304. Further, other embodiments may include any number of fans 312, heat exchangers 310, heat pipes 306, partial EMI sidewalls 307, and vapor chambers 308.

FIGS. 4A-C illustrate perspective views of a system 400 that includes a hybrid cooler and EMI shield with a conductive heat pipe grounding guide 420. In particular, FIG. 4A shows a view of the top side of system 400, FIG. 4B shows a view of the bottom side of system 400, and FIG. 4C shows the heat pipe grounding guide 420 used to ground the heat pipes 406a-b in system 400.

In the illustrated embodiment, system 400 includes a printed circuit board (PCB) 402, an SoC core 404 (e.g., an SoC and other associated components), two fans 412a-b, two heat exchangers 410a-b, two heat pipes 406a-b, a vapor chamber 408, and a heat pipe grounding guide 420.

The heat pipes 406a-b are routed across the system 400 between the heat exchangers 410a-b and around the SoC core 404 (e.g., on the surface of the PCB 402 and below the vapor chamber 408). In particular, the heat pipes 406a-b are routed around the SoC core 404 using a heat pipe ground guide 420, which is a device that guides the respective heat pipes 406a-b around the SoC core 404 while also providing the ground (GND) connections between the heat pipes 406a-b and the PCB 402. For example, as shown in FIG. 4C, the heat pipe grounding guide 420 includes a solder-down wire frame 422, wire protrusions 424 around the frame 422 extending substantially perpendicular to the frame 422, and heat pipe guide slots 426. The wire frame 422 is soldered down on ground contacts (not shown) on the top surface of the PCB 402, which in turn are connected to the main ground (GND) plane of the PCB 402. The guide slots 426 are used to guide the heat pipes 406a-b around the frame 422 on the wire protrusions 424, such that the heat pipes 406a-b sit on the wire protrusions 424 and extend around the frame 422. In this manner, the heat pipe grounding guide 420 grounds the heat pipes 406a-b (e.g., by connecting them to the ground (GND) plane of the PCB 402) and also guides or routes the heat pipes 406a-b around the SoC core 404.

In particular, one of the heat pipes 406a is routed directly between the heat exchangers 410a-b along the north side of the SoC core 404, and the other heat pipe 406b is routed between the heat exchangers 410a-b along the west, south, and cast sides of the SoC core 404. In this manner, the heat pipes 406a-b collectively surround the SoC core 404 on all sides—without the use of any partial EMI sidewalls—and the vapor chamber 408 covers the top of the SoC core 404, thus forming an enclosure around the SoC core 404. As a result, the heat pipes 406a-b and the vapor chamber 408 collectively function as both a cooling system and an EMI shield for the SoC core 404.

In the illustrated embodiment, the heat pipe grounding guide 420 is designed to route the heat pipes 406a-b along the surface of the PCB 402 (e.g., similar to system 100 of FIG. 1). In other embodiments, however, the heat pipe grounding guide 420 may be modified to route the heat pipes 406a-b along the sides of the PCB 402 (e.g., similar to system 200 of FIG. 2).

FIGS. 5A-C illustrate perspective views of a system 500 that includes a hybrid EMI shield cooler 520 with an EMI gasket 511 to ground the heat pipes 506a-f to a printed circuit board (PCB) 502. In particular, FIG. 5A shows the components of system 500 prior to assembly, FIG. 5B shows the assembled system 500, and FIG. 5C shows the components underneath the vapor chamber 508 in the assembled system 500.

As shown in FIG. 5A, system 500 includes a hybrid EMI shield cooler 520, an EMI gasket 511 (e.g., a conductive foam gasket), and an electronic device 530. The hybrid EMI shield cooler 520 includes multiple heat exchangers 510a-d, multiple heat pipes 506a-f, and a vapor chamber 508. The electronic device 530 includes multiple fans 512a-b, a PCB 502, and various IC components attached and electrically coupled to the PCB 502, including a system-on-a-chip (SoC) package 503 (e.g., an IC package or substrate 503 containing an SoC die 504), memory chips 505, and voltage regulators 507, which are collectively referred to herein as the “SoC core.”

The EMI gasket 511 is positioned between the PCB 502 and portions of the heat pipes 506a-f underneath the vapor chamber 508, such that the EMI gasket 511 electrically couples the heat pipes 506a-f to ground contacts (not shown) on the PCB 502, thus grounding the hybrid EMI shield cooler 520.

The heat pipes 506a-f are routed around the SoC core (e.g., on the surface of the PCB 502 and below the vapor chamber 508) to the heat exchangers 510a-d. In particular, heat pipes 506a-c are routed along the west side and portions of the north and south sides of the SoC core, and heat pipes 506d-f are routed along the east side and the remaining portions of the north and south sides of the SoC core. In this manner, the heat pipes 506a-f collectively surround the SoC core on all sides—without the use of any partial EMI sidewalls—and the vapor chamber 508 covers the top of the SoC core, thus forming an enclosure around the SoC core. As a result, the heat pipes 506a-f and the vapor chamber 508 collectively function as both a cooling system and an EMI shield for the SoC core.

FIGS. 6A-C illustrate various grounding mechanisms for a hybrid cooler and EMI shield in a system 600 with one or more heat pipes 106 routed along the sides of a printed circuit board (PCB) 102 (e.g., similar to system 200 of FIG. 2). In particular, FIGS. 6A, 6B, and 6C each show system 600 before and after assembly using different grounding mechanisms, including conductive foam 610, rigid conductors or clips 612, and conductive spring clips 614a-b.

In FIG. 6A, conductive foam 610 is attached to the top surface of the PCB 102 such that the foam 610 extends over the sides or edges of the PCB 102 where the heat pipes 106 will be routed. When the heat pipes 106 and vapor chamber 108 are assembled and attached, the heat pipes 106 come in contact with the conductive foam 610, thus creating an electrical ground connection between the heat pipes 106 and the PCB 102.

In FIG. 6B, rigid conductors 612 (e.g., surface-mount technology (SMT) clips) are attached to the bottom surface of the PCB 102, such that the rigid conductors 612 extend over the sides or edges of the PCB 102 where the heat pipes 106 will be routed. When the heat pipes 106 and vapor chamber 108 are assembled and attached, the heat pipes 106 come in contact with the rigid conductors 612, thus creating an electrical ground connection between the heat pipes 106 and the PCB 102. In some embodiments, conductive foam (e.g., foam 610) may optionally be inserted between the rigid conductors 612 and the heat pipes 106 for a more reliable ground connection.

In FIG. 6C, conductive spring clips 614a-b are attached to the top surface of the PCB 102 and to the heat pipes 106, respectively. In this manner, when the heat pipes 106 and vapor chamber 108 are assembled and attached, the clips 614a on the PCB 102 mate with the clips 614b on the heat pipes 106, thus creating an electrical ground connection between the heat pipes 106 and the PCB 102.

Further, in some embodiments, the heat pipe grounding guide 420 from FIGS. 4A-C may be used to ground the heat pipes 106, with modifications to route the heat pipes 106 along the sides of the PCB 102 instead of on the surface of the PCB 102.

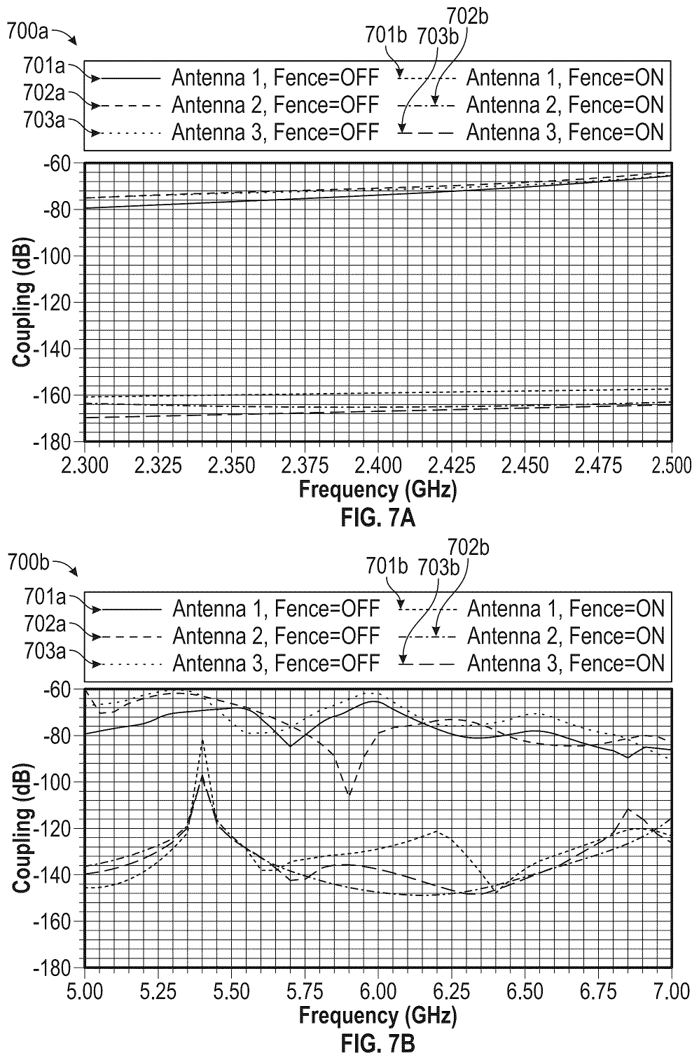

FIGS. 7A-B illustrate graphs 700a,b of the performance of a hybrid EMI shield cooling system with respect to shielding EMI from nearby Wi-Fi antennas. In particular, graphs 700a-b show the electromagnetic coupling (decibels (dB)) between three aggressors and three nearby Wi-Fi antennas—both with and without a hybrid EMI shield cooling system on the aggressors—for Wi-Fi frequency ranges 2.3-2.5 gigahertz (GHz) (FIG. 7A) and Wi-Fi frequency ranges 5-7 GHZ (FIG. 7B), using the system 400 of FIGS. 4A-C. In particular, the coupling is shown for each antenna 701, 702, and 703 both without (e.g., 701a, 702a, 703a) and with (e.g., 701b, 702b, 703b) the EMI shield/fence on the aggressors. As shown by these graphs 700a-b, the EMI shield cooling system provides good EMI shielding effectiveness, with average shielding effectiveness of approximately 50-80 dB (e.g., ˜80 dB for Wi-Fi frequency ranges 2.3-2.5 GHZ and ˜50 dB for Wi-Fi frequency ranges 5-7 GHZ).

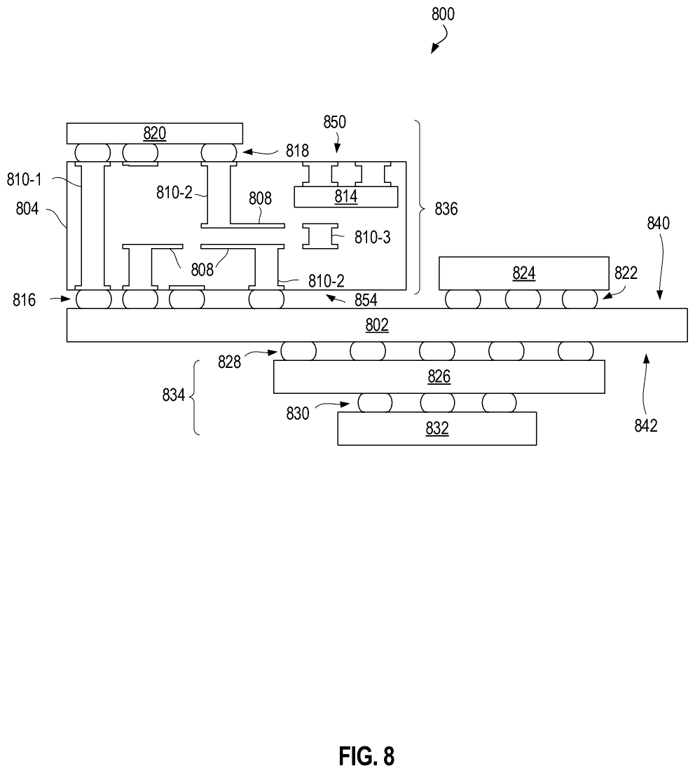

FIG. 8 is a cross-sectional side view of an integrated circuit device assembly 800 that may include any of the embodiments disclosed herein. In some embodiments, for example, the integrated circuit device assembly 800 may include one or more hybrid coolers/EMI shields around any of the IC components 820, 824, 826, 832 on the circuit board 802.

In some embodiments, the integrated circuit device assembly 800 may be a microelectronic assembly. The integrated circuit device assembly 800 includes a number of components disposed on a circuit board 802 (which may be a motherboard, system board, mainboard, etc.). The integrated circuit device assembly 800 includes components disposed on a first face 840 of the circuit board 802 and an opposing second face 842 of the circuit board 802; generally, components may be disposed on one or both faces 840 and 842. Any of the integrated circuit components discussed below with reference to the integrated circuit device assembly 800 may take the form of any suitable ones of the embodiments of the microelectronic assemblies disclosed herein.

In some embodiments, the circuit board 802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate. The integrated circuit device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 816 may serve as the coupling components illustrated or described for any of the substrate assembly or substrate assembly components described herein, as appropriate.

The package-on-interposer structure 836 may include an integrated circuit component 820 coupled to an interposer 804 by coupling components 818. The coupling components 818 may take any suitable form for the application, such as the forms discussed above with reference to the coupling components 816. Although a single integrated circuit component 820 is shown in FIG. 8, multiple integrated circuit components may be coupled to the interposer 804; indeed, additional interposers may be coupled to the interposer 804. The interposer 804 may provide an intervening substrate used to bridge the circuit board 802 and the integrated circuit component 820.

The integrated circuit component 820 may be a packaged or unpackaged integrated circuit product that includes one or more integrated circuit dies and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 820, a single monolithic integrated circuit die comprises solder bumps attached to contacts on the die. The solder bumps allow the die to be directly attached to the interposer 804. The integrated circuit component 820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 820 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCPS) or multi-chip module (MCM).

In addition to comprising one or more processor units, the integrated circuit component 820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 804 may spread connections to a wider pitch or reroute a connection to a different connection. For example, the interposer 804 may couple the integrated circuit component 820 to a set of ball grid array (BGA) conductive contacts of the coupling components 816 for coupling to the circuit board 802. In the embodiment illustrated in FIG. 8, the integrated circuit component 820 and the circuit board 802 are attached to opposing sides of the interposer 804; in other embodiments, the integrated circuit component 820 and the circuit board 802 may be attached to a same side of the interposer 804. In some embodiments, three or more components may be interconnected by way of the interposer 804.

In some embodiments, the interposer 804 may be formed as a PCB, including multiple metal layers separated from one another by layers of dielectric material and interconnected by electrically conductive vias. In some embodiments, the interposer 804 may be formed of an epoxy resin, a fiberglass-reinforced epoxy resin, an epoxy resin with inorganic fillers, a ceramic material, or a polymer material such as polyimide. In some embodiments, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810, including but not limited to through hole vias 810-1 (that extend from a first face 850 of the interposer 804 to a second face 854 of the interposer 804), blind vias 810-2 (that extend from the first or second faces 850 or 854 of the interposer 804 to an internal metal layer), and buried vias 810-3 (that connect internal metal layers).

In some embodiments, the interposer 804 can comprise a silicon interposer. Through silicon vias (TSV) extending through the silicon interposer can connect connections on a first face of a silicon interposer to an opposing second face of the silicon interposer. In some embodiments, an interposer 804 comprising a silicon interposer can further comprise one or more routing layers to route connections on a first face of the interposer 804 to an opposing second face of the interposer 804.

The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art. In embodiments where the interposer is a non-printed circuit board

The integrated circuit device assembly 800 may include an integrated circuit component 824 coupled to the first face 840 of the circuit board 802 by coupling components 822. The coupling components 822 may take the form of any of the embodiments discussed above with reference to the coupling components 816, and the integrated circuit component 824 may take the form of any of the embodiments discussed above with reference to the integrated circuit component 820.

The integrated circuit device assembly 800 illustrated in FIG. 8 includes a package-on-package structure 834 coupled to the second face 842 of the circuit board 802 by coupling components 828. The package-on-package structure 834 may include an integrated circuit component 826 and an integrated circuit component 832 coupled together by coupling components 830 such that the integrated circuit component 826 is disposed between the circuit board 802 and the integrated circuit component 832. The coupling components 828 and 830 may take the form of any of the embodiments of the coupling components 816 discussed above, and the integrated circuit components 826 and 832 may take the form of any of the embodiments of the integrated circuit component 820 discussed above. The package-on-package structure 834 may be configured in accordance with any of the package-on-package structures known in the art.

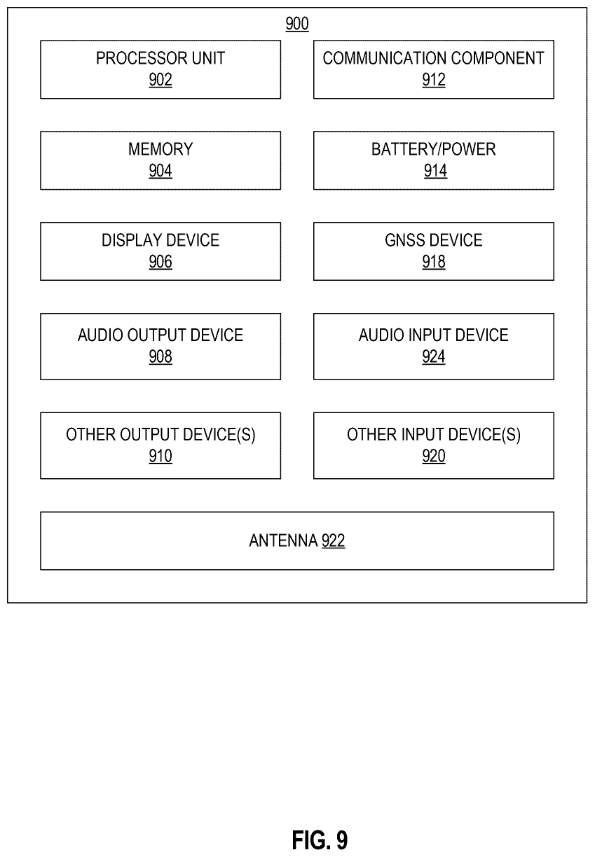

FIG. 9 is a block diagram of an example electrical device 900 that may include one or more of the embodiments disclosed herein. In some embodiments, for example, the electrical device 900 may include one or more hybrid coolers/EMI shields according to any of the embodiments disclosed herein.

A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards, mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 900 can comprise one or more processor units 902 that are heterogeneous or asymmetric to another processor unit 902 in the electrical device 900. There can be a variety of differences between the processing units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include other output device(s) 910 (or corresponding interface circuitry, as discussed above). Examples of the other output device(s) 910 may include an audio codec, a video codec, a printer, a wired or wireless transmitter for providing information to other devices, or an additional storage device.

The electrical device 900 may include other input device(s) 920 (or corresponding interface circuitry, as discussed above). Examples of the other input device(s) 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a display device (e.g., monitor, television), a set-top box, an entertainment control unit, a video game console, a video playback device, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/−10% of a target value (unless otherwise specified). Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “under”, “between”, “adjacent”, “to”, and “on” as used herein may refer to a relative position of one layer or component with respect to other layers or components. For example, one layer “over”, “under”, or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

The term “package” generally refers to a self-contained carrier of one or more dice, where the dice are attached to or embedded in the package substrate, and may be encapsulated for protection, with integrated or wire-bonded interconnects between the dice, along with leads, pins, or bumps located on the external portions of the package substrate. The package may contain a single die, or multiple dice, providing respective functions. The package may be mounted on a printed circuit board for interconnection with other packaged integrated circuits and discrete components, forming a larger circuit.

The term “cored” generally refers to a substrate of an integrated circuit package built upon a board, card, or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core may allow for higher-density package architectures, as the through-vias may have relatively large dimensions and pitch compared to high-density interconnects.

The term “land side” generally refers to the side of the substrate of the integrated circuit package closest to the plane of attachment to a printed circuit board, motherboard, or other package. This is in contrast to the term “die side”, which generally refers to the side of the substrate of the integrated circuit package to which the die or dice are attached.

The terms “dielectric” and “dielectric material” generally refer to any type or number of non-electrically conductive materials. In some cases, dielectric material may be used to make up the structure of a package substrate. For example, dielectric material may be incorporated into an integrated circuit package as layers of laminate film or as a resin molded over integrated circuit dice mounted on the substrate.

The term “metallization” generally refers to metal layers formed on, over, and/or through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and may carry the same or similar meaning.

The term “bump” generally refers to a conductive layer or structure formed on a bond pad, which is typically made of solder or metal and has a round or curved shape, hence the term “bump”.

The term “substrate” generally refers to a planar platform comprising dielectric and/or metallization structures. A substrate may mechanically support and electrically couple one or more IC dies on a single platform, with encapsulation of the one or more IC dies by a moldable dielectric material. A substrate may include bumps or pads as bonding interconnects on one or both sides. For example, one side of the substrate, generally referred to as the “die side”, may include bumps or pads for chip or die bonding. The opposite side of the substrate, generally referred to as the “land side”, may include bumps or pads for bonding the package to a printed circuit board.

The term “assembly” generally refers to a grouping of parts into a single functional unit. For example, certain parts may be permanently bonded together, integrated together, and/or mechanically assembled (e.g., where parts may be removable) into a functional unit.

The terms “coupled” or “connected” means a direct or indirect connection, such as a direct electrical, mechanical, magnetic, or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal.

### EXAMPLES

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a device, comprising: a vapor chamber; and one or more heat pipes coupled to the vapor chamber, wherein the heat pipes are at least partially below the vapor chamber, and wherein the heat pipes are to be further coupled to a circuit board such that the heat pipes and the vapor chamber are to form at least a portion of an electromagnetic interference (EMI) shield around at least a portion of integrated circuitry on the circuit board.

Example 2 includes the device of Example 1, wherein the EMI shield comprises a lid and one or more sidewalls, wherein the vapor chamber is the lid, and wherein the heat pipes are one or more of the sidewalls.

Example 3 includes the device of Example 2, wherein the one or more sidewalls are a plurality of sidewalls, wherein at least one of the sidewalls is not a heat pipe.

Example 4 includes the device of any of Examples 1-3, wherein the vapor chamber and the heat pipes are to cool the integrated circuitry.

Example 5 includes the device of any of Examples 1-4, further comprising one or more heat exchangers, wherein the heat pipes are coupled to the heat exchangers.

Example 6 includes the device of Example 5, further comprising one or more fans, wherein the heat exchangers are adjacent to the fans.

Example 7 includes the device of any of Examples 1-6, wherein the device is: a hybrid cooler and EMI shield; or an electronic device comprising the circuit board, the integrated circuitry, and a hybrid cooler and EMI shield, wherein the hybrid cooler and EMI shield comprises the vapor chamber and the heat pipes.

Example 8 includes an electromagnetic interference (EMI) shield, comprising: a lid, wherein the lid comprises a vapor chamber; and one or more sidewalls coupled to the lid, wherein the sidewalls comprise one or more heat pipes.

Example 9 includes the EMI shield of Example 8, wherein: the EMI shield is to be coupled to a circuit board to at least partially enclose one or more integrated circuits on the circuit board; and the vapor chamber and the heat pipes are to cool the integrated circuits.

Example 10 includes the EMI shield of any of Examples 8-9, wherein the sidewalls further comprise one or more partial sidewalls.

Example 11 includes a system, comprising: a circuit board; one or more integrated circuits coupled to the circuit board; and an electromagnetic interference (EMI) shield coupled to the circuit board, wherein the EMI shield comprises a lid and one or more sidewalls, wherein the lid and the sidewalls at least partially enclose the integrated circuits, and wherein the sidewalls comprise one or more heat pipes to cool the integrated circuits.

Example 12 includes the system of Example 11, wherein the lid comprises a vapor chamber, wherein the heat pipes are coupled to the vapor chamber.

Example 13 includes the system of any of Examples 11-12, further comprising one or more heat exchangers coupled to the heat pipes.

Example 14 includes the system of Example 13, further comprising one or more fans adjacent to the heat exchangers.

Example 15 includes the system of any of Examples 11-14, wherein the heat pipes are coupled to a surface of the circuit board.

Example 16 includes the system of any of Examples 11-14, wherein the heat pipes are coupled to one or more sides of the circuit board.

Example 17 includes the system of any of Examples 11-16, wherein the circuit board comprises one or more ground contacts, wherein the EMI shield is electrically coupled to the ground contacts.

Example 18 includes the system of Example 17, further comprising a conductive heat pipe grounding guide, wherein the EMI shield is electrically coupled to the ground contacts via the conductive heat pipe grounding guide.

Example 19 includes the system of Example 17, further comprising a conductive gasket or one or more conductive clips, wherein the EMI shield is electrically coupled to the ground contacts via the conductive gasket or the one or more conductive clips.

Example 20 includes the system of any of Examples 11-19, wherein the one or more integrated circuits comprise at least one of a processor, a memory, or a voltage regulator.

Example 21 includes the system of Examples 11-20, wherein the one or more integrated circuits comprise a system-on-a-chip, wherein the system-on-a-chip comprises one or more of a central processing unit, a graphics processing unit, a network interface controller, a storage device, a memory controller, or an input/output controller.

1. A device, comprising:
a vapor chamber; and
one or more heat pipes coupled to the vapor chamber, wherein the heat pipes are at least partially below the vapor chamber, and wherein the heat pipes are to be further coupled to a circuit board such that the heat pipes and the vapor chamber are to form at least a portion of an electromagnetic interference (EMI) shield around at least a portion of integrated circuitry on the circuit board.

2. The device of claim 1, wherein the EMI shield comprises a lid and one or more sidewalls, wherein the vapor chamber is the lid, and wherein the heat pipes are one or more of the sidewalls.

3. The device of claim 2, wherein the one or more sidewalls are a plurality of sidewalls, wherein at least one of the sidewalls is not a heat pipe.

4. The device of claim 1, wherein the vapor chamber and the heat pipes are to cool the integrated circuitry.

5. The device of claim 4, further comprising one or more heat exchangers, wherein the heat pipes are coupled to the heat exchangers.

6. The device of claim 1, wherein the device is:
a hybrid cooler and EMI shield; or
an electronic device comprising the circuit board, the integrated circuitry, and a hybrid cooler and EMI shield, wherein the hybrid cooler and EMI shield comprises the vapor chamber and the heat pipes.

7. An electromagnetic interference (EMI) shield, comprising:
a lid, wherein the lid comprises a vapor chamber; and
one or more sidewalls coupled to the lid, wherein the sidewalls comprise one or more heat pipes.

8. The EMI shield of claim 7, wherein:
the EMI shield is to be coupled to a circuit board to at least partially enclose one or more integrated circuits on the circuit board; and
the vapor chamber and the heat pipes are to cool the integrated circuits.

9. The EMI shield of claim 7, wherein the sidewalls further comprise one or more partial sidewalls.

10. A system, comprising:
a circuit board;
one or more integrated circuits coupled to the circuit board; and
an electromagnetic interference (EMI) shield coupled to the circuit board, wherein the EMI shield comprises a lid and one or more sidewalls, wherein the lid and the sidewalls at least partially enclose the integrated circuits, and wherein the sidewalls comprise one or more heat pipes to cool the integrated circuits.

11. The system of claim 10, wherein the lid comprises a vapor chamber, wherein the heat pipes are coupled to the vapor chamber.

12. The system of claim 10, further comprising one or more heat exchangers coupled to the heat pipes.

13. The system of claim 12, further comprising one or more fans adjacent to the heat exchangers.

14. The system of claim 10, wherein the heat pipes are coupled to a surface of the circuit board.

15. The system of claim 10, wherein the heat pipes are coupled to one or more sides of the circuit board.

16. The system of claim 10, wherein the circuit board comprises one or more ground contacts, wherein the EMI shield is electrically coupled to the ground contacts.

17. The system of claim 16, further comprising a conductive heat pipe grounding guide, wherein the EMI shield is electrically coupled to the ground contacts via the conductive heat pipe grounding guide.

18. The system of claim 16, further comprising a conductive gasket or one or more conductive clips, wherein the EMI shield is electrically coupled to the ground contacts via the conductive gasket or the one or more conductive clips.

19. The system of claim 10, wherein the one or more integrated circuits comprise at least one of a processor, a memory, or a voltage regulator.

20. The system of claim 10, wherein the one or more integrated circuits comprise a system-on-a-chip, wherein the system-on-a-chip comprises one or more of a central processing unit, a graphics processing unit, a network interface controller, a storage device, a memory controller, or an input/output controller.
